(19) United States
(12) Patent Application Publication
(10) Pub. No.: US 2025/0363277 A1
(43) Pub. Date: Nov. 27, 2025

(54) DESIGN-FOR-TEST CIRCUITS AND METHODS OF OPERATING THE SAME

(71) Applicant: Taiwan Semiconductor Manufacturing Company, Ltd., Hsinchu (TW)

(72) Inventors: Chia-En Huang, Hsinchu City (TW); Jui-Che Tsai, Hsinchu City (TW); Ku-Feng Lin, Hsinchu City (TW); Yih Wang, Hsinchu City (TW)

(73) Assignee: Taiwan Semiconductor Manufacturing Company, Ltd., Hsinchu (TW)

(21) Appl. No.: 19/294,609

(22) Filed: Aug. 8, 2025

Related U.S. Application Data
(63) Continuation of application No. 18/350,512, filed on Jul. 11, 2023.
(60) Provisional application No. 63/488,276, filed on Mar. 3, 2023.

(51) Int. Cl. G06F 30/333; G01R 31/317; G01R 31/3177; G01R 31/3185; H03K 19/173

(52) U.S. Cl. CPC G06F 30/333; G01R 31/31704; G01R 31/31725; G01R 31/3177; G01R 31/318533; H03K 19/1737

(57) ABSTRACT

A circuit includes a plurality of first inputs corresponding to a first I/O of an I/O circuit and configured to receive at least a first input signal or a second input signal; a multiplexer compressor coupled to the plurality of first inputs, and configured to alternately form a first testing path for the first input signal and a second testing path for the second input signal; a first output configured to provide a first output signal, through one of the first testing path or the second testing path, as a shifted version of a third input signal; and a second output configured to provide a second output signal, through one of the first testing path or the second testing path, as a captured version of the first input signal or the second input signal.

### CROSS-REFERENCE TO RELATED APPLICATION

The present application is a continuation of U.S. patent application Ser. No. 18/350,512, filed on Jul. 11, 2023, which claims priority to and the benefit of U.S. Provisional Application No. 63/488,276, filed Mar. 3, 2023, the entire disclosures of each of which are incorporated herein by reference for all purposes.

### BACKGROUND

Integrated circuits such as, for example, system-on-chips (SoCs) integrate various digital and sometimes analog components on a single chip. Integrated circuits may have manufacturing defects such as physical failures and fabrication defects that cause the integrated circuits to malfunction. In general, the integrated circuits are typically tested to detect manufacturing defects. Design for test or design for testability (DFT) techniques add testability features to integrated circuits that allow automatic test equipment (ATEs) to execute various fault tests using test patterns.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an integrated circuit including an input/output (I/O) circuit, in accordance with some embodiments.

FIG. 2 illustrates a circuit diagram of an example I/O circuit, in accordance with some embodiments.

FIG. 3 illustrates respective example waveforms of signals when operating the I/O circuit of FIG. 2, in accordance with some embodiments.

FIG. 4 illustrates a circuit diagram of another example I/O circuit, in accordance with some embodiments.

FIG. 5 illustrates a circuit diagram of yet another example I/O circuit, in accordance with some embodiments.

FIG. 6 illustrates a circuit diagram of yet another example I/O circuit, in accordance with some embodiments.

FIG. 7 illustrates a circuit diagram of yet another example I/O circuit, in accordance with some embodiments.

FIG. 8 illustrates a circuit diagram of yet another example I/O circuit, in accordance with some embodiments.

FIG. 9 illustrates a circuit diagram of yet another example I/O circuit, in accordance with some embodiments.

FIG. 10 and FIG. 11 respectively illustrate example logic gates for processing a switching control signal, in accordance with some embodiments.

FIG. 12 is an example flow chart of a method for testing an I/O circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Over the past several technology generations (or nodes), the size of transistors has been ever increasingly shrunk for delivering improvement in performance, power efficiency, and area density (PPA). Along with such a trend, design-technology co-optimization (DTCO), combined with intrinsic scaling, have been adopted to achieve the desired logic density and die cost/area reduction. As indicated by its name, DTCO refers to optimizing design and process technology together to improve performance, power efficiency, transistor density, and cost. With DTCO, the result is a robust 1.7 times increase in logic density, and a healthy 35-40% per generation chip size reduction for the same design, even when the “less-scalable” areas of the chip, such as analog and I/O are included.

DTCO for a new technology node usually involves substantial architectural innovation instead of just delivering the exact same structure as the previous generation, only smaller. As the technology nodes keep shrinking, contribution of DTCO may become increasingly significant. For example, technology affects static random access memory (SRAM) design considerations such as manufacturability, reliability, power, performance, and area. The scaling of SRAM has been one of the most fundamental and challenging issues. SRAM leakage, performance, and density are all of utmost importance and often have conflicting requirements. Accordingly, some DTCO techniques have been proposed to improve every aspect of the manufacturability, reliability, power, performance, and area of SRAM (sometimes referred to as “SRAM DTCO”).

In general, an SRAM circuit includes various components such as, for example, cell arrays and input/output (I/O) circuits operating the cell arrays. Specifically, the I/O circuits can have various sub-blocks, which are sometimes referred to as an I/O base circuit (e.g., pre-chargers, column multiplexers, sensing amplifiers, write drivers, otherwise redundant multiplexers, etc.), an I/O redundancy circuit, an I/O interface circuit (e.g., multiplexers, buffers, etc.), and an I/O DFT circuit (e.g., latches, multiplexers, XOR logic gates, etc.). With the cell arrays implemented in advanced technology nodes, it has become significantly challenging to keep scaling down an area of the cell arrays with a substantial amount (e.g., greater than 5%). However, scaling of the I/O circuits are typically limited by processing (e.g., front-end-of-line processing and/or back-end-of-line processing). Thus, the existing SRAM circuit (or its corresponding design) has not been entirely satisfactory in some aspects.

The present disclosure provides various embodiments of an integrated circuit including a static random access memory (SRAM) device that has been redesigned, in view of the current trend of SRAM DTCO. In one aspect of the present disclosure, the SRAM circuit includes an I/O DFT circuit, instead of utilizing XOR-based compression, that has a multiplexer (MUX)-based compression. For example, the I/O DFT circuit, as disclosed herein, can have a MUX selecting different test (e.g., scan) paths/chains, or compressing plural scan paths/chains. Such a MUX is sometimes referred to as a MUX compressor. With the disclosed MUX-based compression, a fewer number of transistors is needed to implement the I/O DFT circuit, which can advantageously save a total area of the SRAM circuit. Further, using the MUX compressor to switch between different scan paths, the input signals (or input pins) of a corresponding I/O interface circuit are necessarily required to tie to a fix logic state while testing one of the scan paths. In another aspect of the present disclosure, a plural number of I/O pins can share a common MUX compressor, which can further help to shrink the area depending on the number of I/O pins (e.g., by 25% with one I/O pin, by 38% with two I/O pins, 42% with three I/O pins, 44% with four I/O pins).

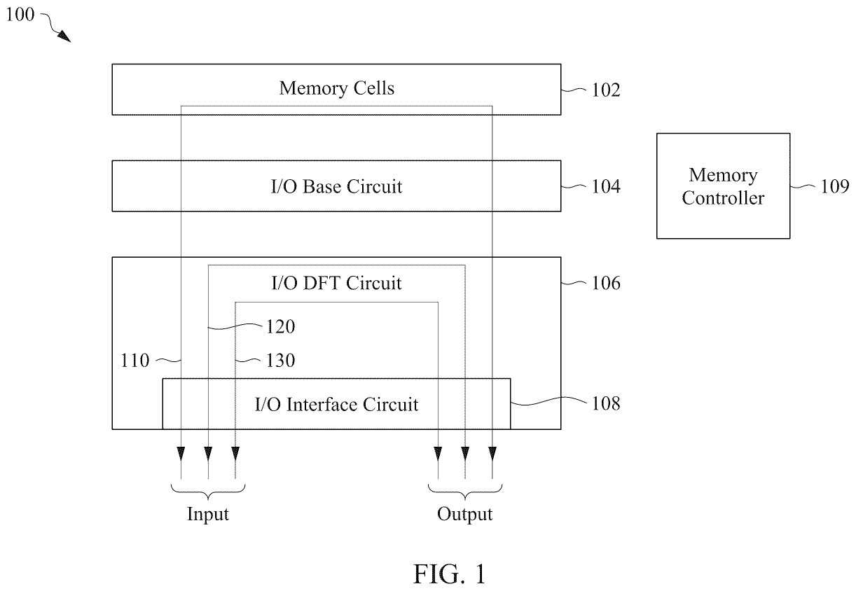

FIG. 1 illustrates a block diagram of an integrated circuit 100, in accordance with various embodiments. The integrated circuit 100 includes a memory circuit (e.g., an SRAM circuit) that includes one or more cell arrays and one or more I/O circuits. It, however, should be understood that the integrated circuit 100 is simplified for illustration purposes. Thus, the integrated circuit 100 can include any of various other components (or blocks) while remaining within the scope of the preset disclosure.

As shown, the integrated circuit 100 includes memory cells 102, an I/O base circuit 104, an I/O DFT circuit 106, and an I/O interface circuit 108. In various embodiments, the integrated circuit 100 can further include a memory controller 109 for providing the I/O base circuit 104, the I/O DFT circuit 106, and/or the I/O interface circuit 108 with one or more control signals (e.g., a Sense Amplifier Enable (SAE) signal, a Built-In-Self-Test (BIST) signal, a Scan Shift Enable (SSE) signal, a Scan Capture Enable (SCE) signal, a clock (CLK/KD) signal, a Switch D/B (SDB) signal, etc.), each of which can be a periodic or aperiodic signal. Some of such control signals may be discussed in further detail below. In other words, the memory controller 109 can be operatively coupled to each of the I/O base circuit 104, the I/O DFT circuit 106, and the I/O interface circuit 108. In the illustrated embodiment of FIG. 1, the I/O interface circuit 108 is part of or integrated into to the I/O DFT circuit 106. However, it should be appreciated that the I/O interface circuit 108 and the I/O DFT circuit 106 may be formed as separate blocks, while remaining within the scope of the present disclosure.

The memory cells 102 may include a plural number of memory bit cells (e.g., SRAM cells), or otherwise storage units. Each of the memory bit cells is capable of storing or recording at least a single bit of data (e.g., a logic 1 or 0). The memory bit cells can be formed as one or more memory arrays. The I/O base circuit 104 is operatively coupled to the memory cells 102 to operate (e.g., read, write, or otherwise access) the memory cells 102, and may include one or more pre-chargers, one or more column multiplexers, one or more sensing amplifiers, one or more write drivers, and one or more otherwise redundant multiplexers. The I/O DFT circuit 106 is operatively coupled to the I/O base circuit 104 to test at least a portion of the integrated circuit 100, which will be discussed in further detail below. The I/O interface circuit 108 is operatively coupled to the I/O DFT circuit 106, and may include one or more multiplexers and one or more buffers configured to receive input signal(s) and provide output signal(s).

In various embodiments of the present disclosure, the integrated circuit 100 (e.g., the I/O DFT circuit 106) has three different modes of operation: a NORMAL mode, a SHIFT mode, and a CAPTURE mode. In the NORMAL mode, the integrated circuit 100 does not perform any testing; instead, the integrated circuit 100 performs its regular functionality that it is designed to perform, such as enabling reading and writing of data from/to the memory cells 102. In the SHIFT and CAPTURE modes (which may sometimes referred to as SCAN SHIFT and SCAN CAPTURE, respectively), test-related features are invoked, and various testing functionality is performed on the hardware by applying certain input signals to the integrated circuit 100 and comparing the output signals with “designed” output signals that the integrated circuit 100 is designed to produce. If the observed output signal matches the “designed” output signal then the integrated circuit 100 passes the test; if the observed output signal does not match the “designed” output signal, the integrated circuit 100 fails the test. In the SHIFT mode and CAPTURE mode, which can be considered as testing modes, tests are performed on different parts of the integrated circuit 100, as discussed in further detail below.

Referring still to FIG. 1, three different signal paths through respective portions of the integrated circuit 100 are depicted, each path being associated with a respective one of the three modes of operation. A NORMAL path 110 is associated with the NORMAL mode, a SHIFT path 120 is associated with the SHIFT mode, and a CAPTURE path 130 is associated with the CAPTURE mode. These modes (NORMAL, SHIFT, CAPTURE) and corresponding paths will be described in further detail below.

The NORMAL path 110 starts from the I/O interface circuit 108, proceeds through the I/O DFT circuit 106 and the I/O base circuit 104, then through the memory cells 102, then back to the I/O base circuit 104, and then returns to the I/O interface circuit 108. The SHIFT path 120 and CAPTURE path 130 both start from the I/O interface circuit 108, pass through the I/O DFT circuit 106, and return to the I/O interface circuit 108. In some other embodiments, each of the SHIFT path 120 and CAPTURE path 130 can extend into the I/O base circuit 104, while remaining within the scope of the present disclosure. Alternatively stated, the integrated circuit 100 is added with testing capability to test a portion of its I/O circuit (e.g., the I/O DFT circuit 106 in FIG. 1, or the I/O base circuit 104 and I/O DFT circuit 106 in some other embodiments) by sharing components that can be used for both testing purposes and normal operation within a single IC chip, depending on a mode of operation.

With such testing capability, it is easier to develop and apply manufacturing tests for the integrated circuit 100. In some embodiments, manufacturing test is to validate that the IC hardware product contains no manufacturing defects that adversely affect the proper functioning of the IC hardware. The tests are generally driven by test programs that execute in Automatic Test Equipment (ATE) or inside the assembled system itself. In addition to detecting and indicating the presence of defects when a test fails, in some embodiments, tests are able to log diagnostic information about the nature of the encountered test failures. The diagnostic information can be used to locate the source of the failure. In the test, the response of vectors (patterns) from a “good” circuit (one that is known to be operating correctly) is compared against the response of vectors (using same patterns) from a device under test (DUT). If the response matches, the IC is in good condition. Otherwise, the IC contains defects and does not perform the purpose for which it is designed.

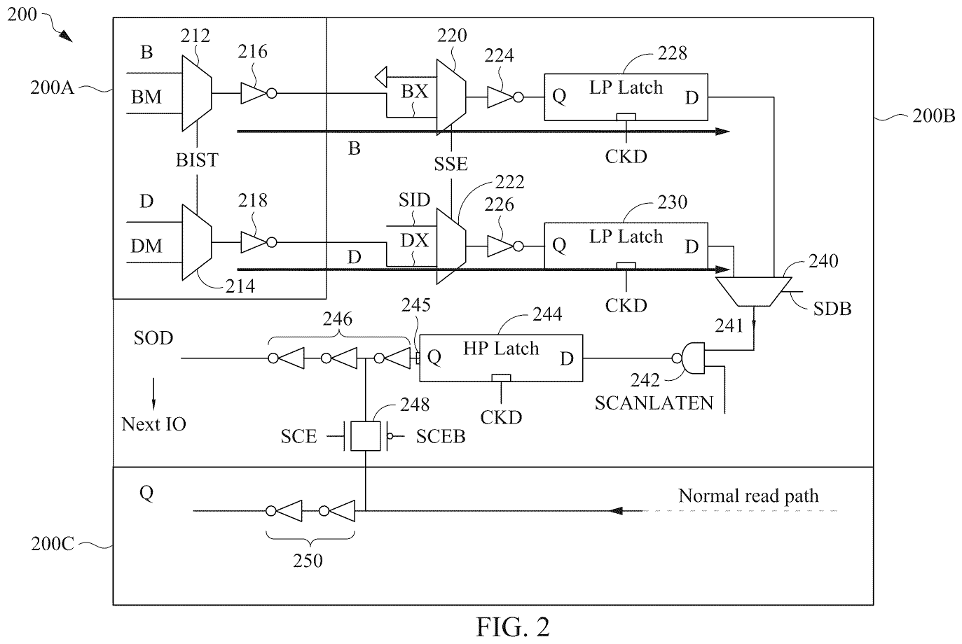

FIG. 2 illustrates an example circuit diagram of a portion of an I/O circuit 200, in accordance with various embodiments. It should be noted that the I/O circuit 200 has been simplified, with some components not expressively illustrated. For example, the I/O circuit 200 includes blocks 200A, 200B, and 200C. The blocks 200A and 200C may correspond to an input portion and an output portion of the I/O interface circuit 108 of the integrated circuit 100, respectively, and the block 200B may correspond to the I/O DFT circuit 106 of the integrated circuit 100. Accordingly, the blocks 200A, 200B, and 200C may sometimes be referred to as “input interface circuit 200A,” “DFT circuit 200B,” and “output interface circuit 200C,” respectively. Although not shown, it should be appreciated that the I/O circuit 200 also includes a corresponding I/O base circuit operatively coupled to the input interface circuit 200A, DFT circuit 200B, and output interface circuit 200C.

As shown, the input interface circuit 200A includes multiplexers 212 and 214, and inverters (or otherwise buffers) 216 and 218. The DFT circuit 200B includes multiplexers 220 and 222, inverters (or otherwise buffers) 224 and 226, low-pass latches 228 and 230, a multiplexer 240, a NAND gate 242, a high-pass latch 244, one or more inverters (or otherwise buffers) 246, and a transmission gate 248. Each of the latches 228-230 and 244 may be implemented as a gated data latch, and the multiplexers 220-222 and 240 may be implemented as a SIMUX configured to shift input data into devices such as latches, in some embodiments. Further, the low-pass latch is configured to allow data to pass through when the corresponding clock phase is low (logic 0); and, in comparison, the high-pass latch is configured to allow data to pass through when the corresponding clock phase is high (logic 1). However, the low-pass latches 228-230 and high-pass latch 244 may be configured differently (e.g., other types of latches), while remaining within the scope of the present disclosure. The output interface circuit 200C includes one or more inverters (or otherwise buffers) 250.

For example, the multiplexer 212 has two inputs to receive input signals “B” and “BM,” respectively, and the multiplexer 214 has two inputs to receive input signals “D” and “DM,” respectively. The input signal D/DM may represent data fed into the I/O circuit 200 while the input signal B/BM may represent a corresponding write enable signal for this specific I/O. Further, the input signals B and BM may be the same but have a first defined time offset with respect to each other; and similarly, the input signals D and DM may be the same but have a second defined time offset with respect to each other. The multiplexers 212 and 214 are controlled by a control signal “BIST,” that is configured to select one of the input signals B and BM for the multiplexer 212, and one of the input signals D and DM for the multiplexer 214. The multiplexer 220 has two inputs, one of which is configured to receive a signal “BX” and the other of which is tied to ground. The signal BX is output by the multiplexer 212 and buffered by the inverter 216. The multiplexer 222 has two inputs, one of which is configured to receive a signal “DX” and the other of which is configured to receive a signal “SID.” The signal DX is output by the multiplexer 218 and buffered by the inverter 218, and the signal SID represents shift input data. The shift input data may be a signal output by a previous scan chain (which will be discussed below).

The multiplexers 220 and 222 are controlled by a control signal “SSE.” In some embodiments, when the control signal SSE is pulled up to logic high, the DFT circuit 200B is switched to the SHIFT mode; and when the control signal SSE is pulled down to logic low, the DFT circuit 200B is switched to the CAPTURE mode. The latch 228 can latch a signal output by the multiplexer 220 (and buffered by the inverter 224) based on a clock signal “CKD.” Similarly, the latch 230 can latch a signal output by the multiplexer 222 (and buffered by the inverter 226) based on the same clock signal CKD. The latches 228 and 230 can then provide their respective output signals to the multiplexer 240 that is controlled by a control signal “SDB.” The control signal SDB may correspond to whether the DFT circuit 220B is testing “B” path or “D” path, as illustrated in FIG. 2. Accordingly, the multiplexer 240 can be controlled to output one of the signals received along the B path or D path according to the control signal SDB. In other words, the multiplexer 240 can compress different scan paths as one, and thus, the multiplexer 240 is sometimes referred to as MUX compressor 240.

With different scan paths sharing a common MUX compressor (e.g., 240), a number of high-pass latch(es) providing output signals can be advantageously reduced. For example in FIG. 2, only one high-pass latch (e.g., 244) is needed for providing an output signal when switching between the SHIFT mode and the CAPTURE mode. Existing technologies based on an XOR-based compressor typically require at least two high-pass latches, one of which is configured for a SHIFT path and the other of which is configured for a CAPTURE path. As such, a total area of the I/O circuit 200 can be reduced by at least about 25%.

In various embodiments of the present disclosure, when testing the D path, the input signal D (or DM) should be provided with at least one logic 1 and one logic 0 (e.g., two pulses). Similarly, when testing the B path, the input signal B (or BM) should be provided with at least one logic 1 and one logic 0 (e.g., two pulses). With the multiplexer 240, when testing the D path, the input signal B (or BM) need not necessarily be tied to ground. Similarly, when testing the B path, the input signal D (or DM) need not necessarily be tied to ground. Stated another way, a logic state of the input signal B (or BM) is independent of a logic state of the input signal D (or DM). Such a flexibility can advantageously ease generation of test patterns for the DFT circuit 220B. Table I below summaries the logic states required to be present at the input signals D and B when testing the B path and D path, respectively, where “X” represents any logic state. Solely for purpose of clarity, the “input signal D” may refer to either signal D or DM, and the “input signal B” may refer to either signal B or BM in the following discussion.

TABLE I

| | Test D | | Test B | |
|---|---|---|---|---|
| D | 0 | 1 | X | X |
| B | X | X | 0 | 1 |

Referring still to FIG. 2, the multiplexer 240 can output a signal 241 to be NAND'ed with a control signal “SCANLATEN.” The latch 244 can latch such a NAND'ed signal based on the clock signal CKD, and output a signal 245 as either signal “SOD (shift output data)” or captured signal “Q.” In some embodiments, when a control signal “SCE” controlling the transmission gate 248 is pulled down to logic low, the output signal 245 may travel through the inverters 246 as the signal SOD; and when the control signal SCE is pulled up to logic high, the output signal 245 may travel through the transmission gate 248 and inverters 250 as the signal Q. Alternatively stated, when the control signal SCE is at logic low, the DFT circuit 200B is switched to the SHIFT mode; and when the control signal SCE is at logic high, the DFT circuit 200B is switched to the CAPTURE mode. That is, the control signals SSE and SCE may be complementary to each other.

In some embodiments, the DFT circuit 200B can switch at least between the SHIFT mode (e.g., 120 of FIG. 1) and the CAPTURE mode (e.g., 130 of FIG. 1). When in the SHIFT mode, the DFT circuit 200B can shift the signal SID received from a previous scan chain as shift output data (sometimes referred to as signal “SOD”) based on the clock signal CKD. Such an SOD signal may serve as an input signal for the next scan chain. The previous scan chain may refer to a first I/O circuit connected to the I/O circuit 200, and the next scan chain may refer to a second I/O circuit connected to the I/O circuit 200. In various embodiments, the first I/O circuit and second I/O circuit may be substantially similar to the I/O circuit 200. Further, the first I/O circuit, the I/O circuit 200, and the second I/O circuit may be connected to one another in series. When in the CAPTURE mode, the DFT circuit 200B can capture the signal D/DM or signal B/BM and output it as the Q signal. Both of the SHIFT mode and the CAPTURE mode can be utilized to test the I/O circuit 200. For example, the SOD signal (or the Q signal) may be compared against an expected “good machine” result. Good machine results are the bit patterns that are expected when the I/O circuit 200 is performed properly. In the event that the SOD/Q signal matches or compares to the good machine pattern, it may be determined that the I/O circuit 200 is performed in the designed manner. In the event that the good machine pattern does not match or miscompares, it may be determined that the I/O circuit 200 is not performed in the designed manner, i.e., failed.

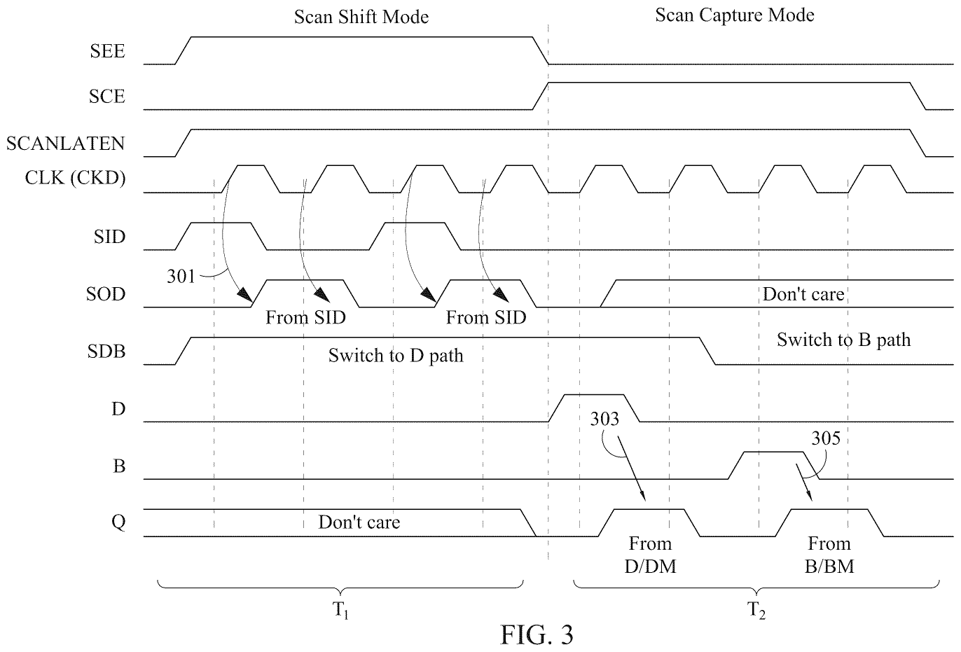

FIG. 3 illustrates example waveforms of some of the above-discussed signals, SSE, SCE, SCANLATEN, CKD, SID, SOD, SDB, D, B, and Q, respectively, in accordance with various embodiments. It should be appreciated that FIG. 3 is merely an illustrative example, and is not intended to limit the scope of the present disclosure. For example, in the waveforms of FIG. 3, during a first period of time (T₁), the DFT circuit 200B is in the SHIFT mode, and during a second, subsequent period of time (T₂), the DFT circuit 200B is in the CAPTURE mode. Further, in the first period of time T₁, the D path is tested; and in the second period of time T₂, the D path is tested, followed by testing the B path.

As shown, during T₁, the control signals SSE and SCE are pull to logic high and logic low, respectively, which causes the DFT circuit 200B to switch to the SHIFT mode. In such a mode, the signal SID received by the multiplexer 222 is shifted as the signal SOD (as indicated by symbolic arrow 301), according to the clock signal CKD (e.g., on a rising edge of the clock signal CKD). Under the SHIFT mode, it generally does not refer to the output signal Q (i.e., “Don't care”). In the example of FIG. 3, the control signal SDB that controls the MUX compressor 240 is pulled to logic high to select the D path. Next, at the beginning of T₂, the control signal SDB still remains at logic high, but the control signals SSE and SCE have transition to logic low and logic high, respectively, which causes the DFT circuit 200B to switch to the CAPTURE mode. In such a mode, the input signal D is captured as the output signal Q (as indicated by symbolic arrow 303). Next, the control signal SDB transitions to logic low, which causes the MUX compressor 240 to select the B path. Thus, the input signal B is captured as the output signal Q (as indicated by symbolic arrow 305). Under the CAPTURE mode, it generally does not refer to the signal SOD (i.e., “Don't care”).

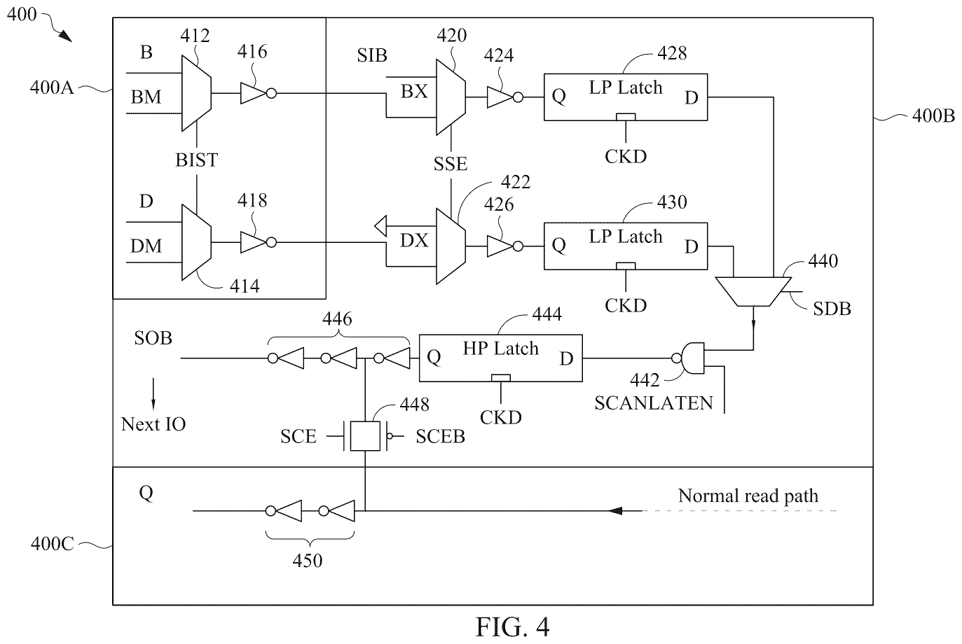

FIG. 4 illustrates an example circuit diagram of a portion of another I/O circuit 400, in accordance with various embodiments. It should be noted that the I/O circuit 400 has been simplified, with some components not expressively illustrated. For example, the I/O circuit 400 includes blocks 400A, 400B, and 400C. The blocks 400A and 400C may correspond to an input portion and an output portion of the I/O interface circuit 108 of the integrated circuit 100, respectively, and the block 400B may correspond to the I/O DFT circuit 106 of the integrated circuit 100. Accordingly, the blocks 400A, 400B, and 400C may sometimes be referred to as “input interface circuit 400A,” “DFT circuit 400B,” and “output interface circuit 400C,” respectively. Although not shown, it should be appreciated that the I/O circuit 400 also includes a corresponding I/O base circuit operatively coupled to the input interface circuit 400A, DFT circuit 400B, and output interface circuit 400C.

In some embodiments, the I/O circuit 400 is substantially similar to the I/O circuit 200 of FIG. 2, and thus, the following discussion will be focused on the difference between the I/O circuit 200 and the I/O circuit 400. The input interface circuit 400A and output interface circuit 400C are identical to the input interface circuit 200A and output interface circuit 200C, respectively. For example, the input interface circuit 400A also includes multiplexers 412 and 414 to receive input signal B/BM and input signal D/DM, respectively, and inverters (or otherwise buffers) 416 and 418; and the output interface circuit 400C also includes one or more inverters (or otherwise buffers) 450 to provide output signal Q. The DFT circuit 400B includes multiplexers 420 and 422, inverters (or otherwise buffers) 424 and 426, low-pass latches 428 and 430, a multiplexer 440, a NAND gate 442, a high-pass latch 444, one or more inverters (or otherwise buffers) 446, and a transmission gate 448. Each of the latches 428-430 and 444 may be implemented as a gated data latch, and the multiplexers 420-422 and 440 may be implemented as a SIMUX configured to shift input data into devices such as latches, in some embodiments. It should be understood that the low-pass latches 428-430 and high-pass latch 444 may be configured differently (e.g., other types of latches), while remaining within the scope of the present disclosure.

However, in the DFT circuit 400B, the multiplexer 420 and the multiplexer 422 are alternatively configured (compared to the DFT circuit 200B of FIG. 2). For example, the multiplexer 420, still controlled by the control signal SSE, has two inputs, one of which is configured to receive a signal “SIB” and the other of which is configured to receive a signal “BX” output by the multiplexer 412 (and then buffered by the inverter 416), respectively; and the multiplexer 422, still controlled by the control signal SSE, has two inputs, one of which is tied to ground and the other of which is configured to receive a signal “DX” output by the multiplexer 414 (and then buffered by the inverter 418). The signal SIB represents a shift input signal output by a previous scan chain. In such a configuration, when the DFT circuit 400B is configured in the SHIFT mode, the DFT circuit 400B, along the B path, can shift a signal output by a previous scan chain (e.g., SIB) as a signal for a next scan chain (e.g., SOB).

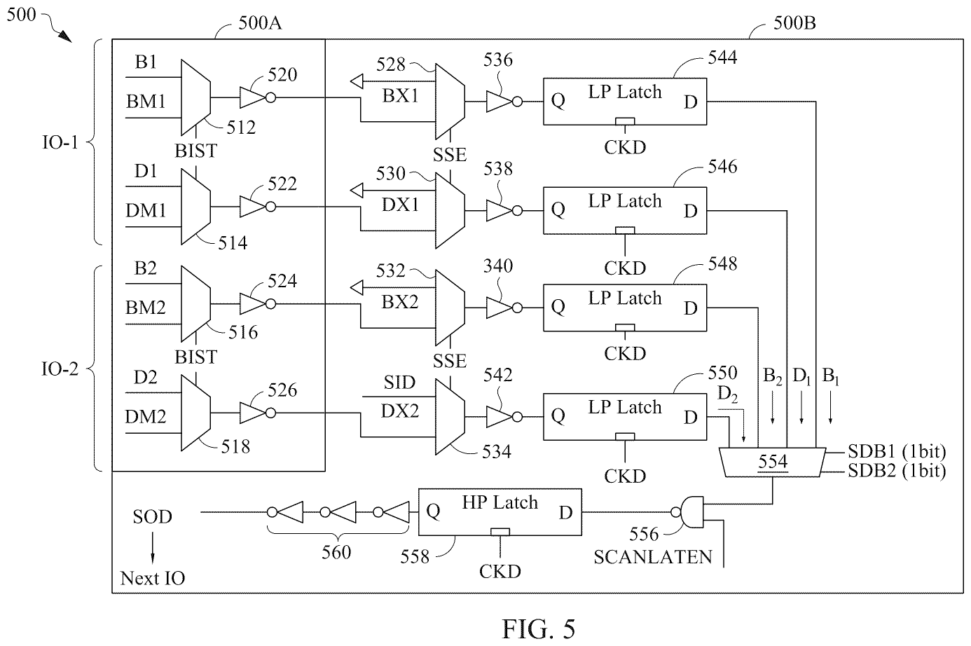

FIG. 5 illustrates an example circuit diagram of a portion of yet another I/O circuit 500, in accordance with various embodiments. It should be noted that the I/O circuit 500 has been simplified, with some components not expressively illustrated. For example, the I/O circuit 500 includes blocks 500A and 500B. The block 500A may correspond to an input portion of the I/O interface circuit 108 of the integrated circuit 100, and the block 500B may correspond to the I/O DFT circuit 106 of the integrated circuit 100. Accordingly, the blocks 500A and 500B may sometimes be referred to as “input interface circuit 500A” and “DFT circuit 500B,” respectively. Although not shown, it should be appreciated that the I/O circuit 500 also includes corresponding I/O base circuit and output interface circuit operatively coupled to the DFT circuit 500B and input interface circuit 500A.

In some embodiments, the I/O circuit 500 is substantially similar to the I/O circuit 200 of FIG. 2, and thus, the following discussion will be focused on the difference between the I/O circuit 200 and the I/O circuit 500. The input interface circuit 500A is similar to the input interface circuit 200A except that the input interface circuit 500A has more than one set of inputs. For example, in addition to multiplexers 512 and 514 configured to receive first input signal B₁/BM₁ and first input signal D₁/DM₁, respectively, and corresponding inverters (or otherwise buffers) 520 and 522, the input interface circuit 500A includes multiplexers 516 and 518 configured to receive second input signal B₂/BM₂ and second input signal D₂/DM₂, respectively, and corresponding inverters (or otherwise buffers) 524 and 526. The first input signals B₁/BM₁/D₁/DM₁ may sometimes be referred to as “first I/O” or “IO-1,” and the second input signals B₂/BM₂/D₂/DM₂ may sometimes be referred to as “second I/O” or “IO-2.”

With such an increasing number of input signals (e.g., the first I/O and second I/O), in addition to multiplexers, inverters, and latches (e.g., multiplexers 528 and 530, inverters 536 and 538, and low-pass latches 544 and 546) coupled to the first I/O, the DFT circuit 500B includes multiplexers 532 and 534, inverters (or otherwise buffers) 540 and 542, and low-pass latches 548 and 550 coupled to the second I/O. The DFT circuit 500B similarly includes a multiplexer 554, a NAND gate 556, a high-pass latch 558, and one or more inverters (or otherwise buffers) 560. It should be understood that the low-pass latches 544-550 and high-pass latch 558 may be configured differently (e.g., other types of latches), while remaining within the scope of the present disclosure.

In some embodiments, the multiplexer 554 can compress different scan paths from different I/O's, e.g., path B₁ and path D₁ from the first I/O, path B₂ and path D₂ from the second I/O. Accordingly, the multiplexer 554 is sometimes referred to as “MUX compressor 554.” The MUX compressor 554 can be controlled by two control signals SDB₁ and SDB₂, each of which may have one bit to identify a selected scan path. The signal SDB₁ may correspond to the first I/O (e.g., selecting the path B₁ or D₁), and the signal SDB₂ may correspond to the second I/O (e.g., selecting the path B₂ or D₂). For example, combinations of bits of the signal SDB₁ and the signal SDB₂, (0, 0), (1, 0), (0, 1), and (1, 1), may correspond to the paths B₁, D₁, B₂, and D₂, respectively. In some embodiments, only one of the multiplexers 528 to 534 (e.g., 534) has one of its inputs to receive signal SID (output from a previous scan chain), while the others of the multiplexers 528 to 534 each have one its inputs tied to ground.

With different scan paths sharing a common MUX compressor (e.g., 554), a number of high-pass latch(es) providing output signals can be advantageously reduced. For example in FIG. 5, only one high-pass latch (e.g., 558) is needed for providing an output signal when switching between the SHIFT mode and the CAPTURE mode. Existing technologies based on an XOR-based compressor typically require at least two high-pass latches, one of which is configured for a SHIFT path and the other of which is configured for a CAPTURE path. As such, a total area of the I/O circuit 500 can be reduced by at least about 38%.

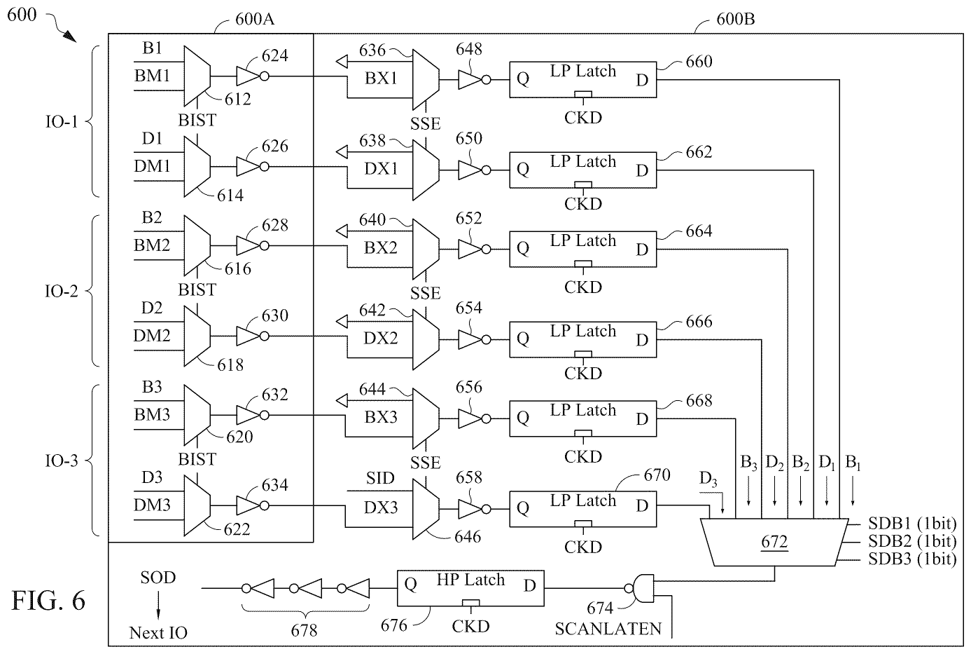

FIG. 6 illustrates an example circuit diagram of a portion of yet another I/O circuit 600, in accordance with various embodiments. It should be noted that the I/O circuit 600 has been simplified, with some components not expressively illustrated. For example, the I/O circuit 600 includes blocks 600A and 600B. The block 600A may correspond to an input portion of the I/O interface circuit 108 of the integrated circuit 100, and the block 600B may correspond to the I/O DFT circuit 106 of the integrated circuit 100. Accordingly, the blocks 600A and 600B may sometimes be referred to as “input interface circuit 600A” and “DFT circuit 600B,” respectively. Although not shown, it should be appreciated that the I/O circuit 600 also includes corresponding I/O base circuit and output interface circuit operatively coupled to the DFT circuit 600B and input interface circuit 600A.

In some embodiments, the I/O circuit 600 is substantially similar to the I/O circuit 200 of FIG. 2, and thus, the following discussion will be focused on the difference between the I/O circuit 200 and the I/O circuit 600. The input interface circuit 600A is similar to the input interface circuit 200A except that the input interface circuit 600A has more than one set of inputs. For example, in addition to multiplexers 612 and 614 configured to receive first input signal B₁/BM₁ and first input signal D₁/DM₁, respectively, and corresponding inverters (or otherwise buffers) 624 and 626, the input interface circuit 600A includes multiplexers 616 and 618 configured to receive second input signal B₂/BM₂ and second input signal D₂/DM₂, respectively, corresponding inverters (or otherwise buffers) 628 and 630, multiplexers 620 and 622 configured to receive third input signal B₃/BM₃ and second input signal D₃/DM₃, respectively, and corresponding inverters (or otherwise buffers) 632 and 634. The first input signals B₁/BM₁/D₁/DM₁ may sometimes be referred to as “first I/O” or “IO-1,” the second input signals B₂/BM₂/D₂/DM₂ may sometimes be referred to as “second I/O” or “IO-2,” and the third input signals B₃/BM₃/D₃/DM₃ may sometimes be referred to as “third I/O” or “IO-3.”

With such an increasing number of input signals (e.g., the first I/O, second I/O, and third I/O), in addition to multiplexers, inverters, and latches (e.g., multiplexers 636 and 638, inverters 648 and 650, and low-pass latches 660 and 662) coupled to the first I/O, the DFT circuit 600B includes multiplexers 640 and 642, inverters (or otherwise buffers) 652 and 654, and low-pass latches 664 and 666 coupled to the second I/O, and multiplexers 644 and 646, inverters (or otherwise buffers) 656 and 658, and low-pass latches 668 and 670 coupled to the third I/O. The DFT circuit 600B similarly includes a multiplexer 672, a NAND gate 674, a high-pass latch 676, and one or more inverters (or otherwise buffers) 678. It should be understood that the low-pass latches 660-670 and high-pass latch 676 may be configured differently (e.g., other types of latches), while remaining within the scope of the present disclosure.

In some embodiments, the multiplexer 672 can compress different scan paths from different I/O's, e.g., path B₁ and path D₁ from the first I/O, path B₂ and path D₂ from the second I/O, and path B₃ and path D₃ from the third I/O. Accordingly, the multiplexer 672 is sometimes referred to as “MUX compressor 672.” The MUX compressor 672 can be controlled by two control signals SDB₁, SDB₂, and SDB₃, each of which may have one bit to identify a selected scan path. The signal SDB₁ may correspond to the first I/O (e.g., selecting the path B₁ or D₁), the signal SDB₂ may correspond to the second I/O (e.g., selecting the path B₂ or D₂), and the signal SDB₃ may correspond to the third I/O (e.g., selecting the path B₃ or D₃). In some embodiments, only one of the multiplexers 636 to 646 (e.g., 646) has one of its inputs to receive signal SID (output from a previous scan chain), while the others of the multiplexers 636 to 646 each have one its inputs tied to ground.

With different scan paths sharing a common MUX compressor (e.g., 672), a number of high-pass latch(es) providing output signals can be advantageously reduced. For example in FIG. 6, only one high-pass latch (e.g., 676) is needed for providing an output signal when switching between the SHIFT mode and the CAPTURE mode. Existing technologies based on an XOR-based compressor typically require at least two high-pass latches, one of which is configured for a SHIFT path and the other of which is configured for a CAPTURE path. As such, a total area of the I/O circuit 600 can be reduced by at least about 42%. With a more number of I/O's compressed by a common MUX compressor, the area of a corresponding I/O circuit may be shrunk further. For example, in an I/O circuit having four I/O's compressed by the disclosed common MUX compressor, a total area of such an I/O circuit can be reduced by at least about 44%, when compared to the existing design using an XOR-based compressor.

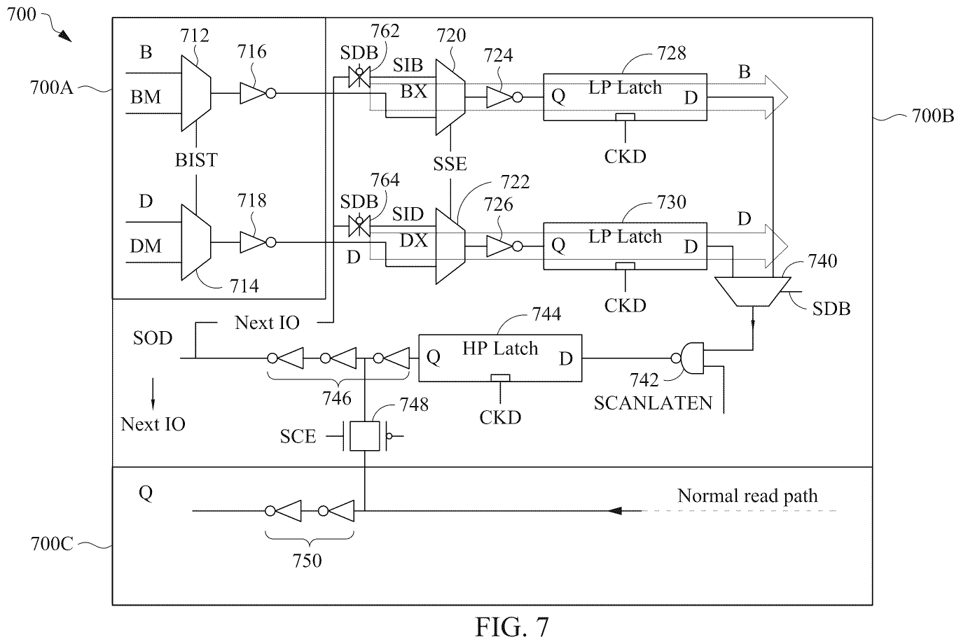

FIG. 7 illustrates an example circuit diagram of a portion of yet another I/O circuit 700, in accordance with various embodiments. It should be noted that the I/O circuit 700 has been simplified, with some components not expressively illustrated. For example, the I/O circuit 700 includes blocks 700A, 700B, and 700C. The blocks 700A and 700C may correspond to an input portion and an output portion of the I/O interface circuit 108 of the integrated circuit 100, respectively, and the block 700B may correspond to the I/O DFT circuit 106 of the integrated circuit 100. Accordingly, the blocks 700A, 700B, and 700C may sometimes be referred to as “input interface circuit 700A,” “DFT circuit 700B,” and “output interface circuit 700C,” respectively. Although not shown, it should be appreciated that the I/O circuit 700 also includes a corresponding I/O base circuit operatively coupled to the input interface circuit 700A, DFT circuit 700B, and output interface circuit 700C.

In some embodiments, the I/O circuit 700 is substantially similar to the I/O circuit 200 of FIG. 2, and thus, the following discussion will be focused on the difference between the I/O circuit 200 and the I/O circuit 700. The input interface circuit 700A and output interface circuit 700C are identical to the input interface circuit 200A and output interface circuit 200C, respectively. For example, the input interface circuit 700A also includes multiplexers 712 and 714 to receive input signal B/BM and input signal D/DM, respectively, and inverters (or otherwise buffers) 716 and 718; and the output interface circuit 700C also includes one or more inverters (or otherwise buffers) 750 to provide output signal Q. The DFT circuit 700B includes multiplexers 720 and 722, inverters (or otherwise buffers) 724 and 726, low-pass latches 728 and 730, a multiplexer 740, a NAND gate 742, a high-pass latch 744, one or more inverters (or otherwise buffers) 746, and a transmission gate 748. Each of the latches 728-730 and 744 may be implemented as a gated data latch, and the multiplexers 720-722 and 740 may be implemented as a SIMUX configured to shift input data into devices such as latches, in some embodiments. It should be understood that the low-pass latches 728-730 and high-pass latch 744 may be configured differently (e.g., other types of latches), while remaining within the scope of the present disclosure.

Different from the DFT circuit 200B, the DFT circuit 700B further includes transmission gates 762 and 764 coupled to the inputs of the multiplexers 720 and 722, respectively. Specifically, the transmission gate 762 is coupled between the output node of the DFT circuit 700B (that provides the signal SOD) and one of the inputs of the multiplexer 720, and the transmission gate 764 is coupled between the output node of the DFT circuit 700B (that provides the signal SOD) and one of the inputs of the multiplexer 722. Each of the transmission gates 762 and 764 is controlled by the switching control signal SDB that selects one of the B path or D path. In such a configuration, when a first one of the B path or D path is tested as having potential issues, a second one of the B path or D path can be tested again to assure whether the issues along the first tested path are confirmed. Further, when the DFT circuit 700B is coupled to multiple IO's, these IO's should be configured for testing either their respective B paths or D paths. In an example where the DFT circuit 700B is coupled to a first IO and a second IO, when the B path for the first IO is tested, the second IO should be configured for testing its B path only.

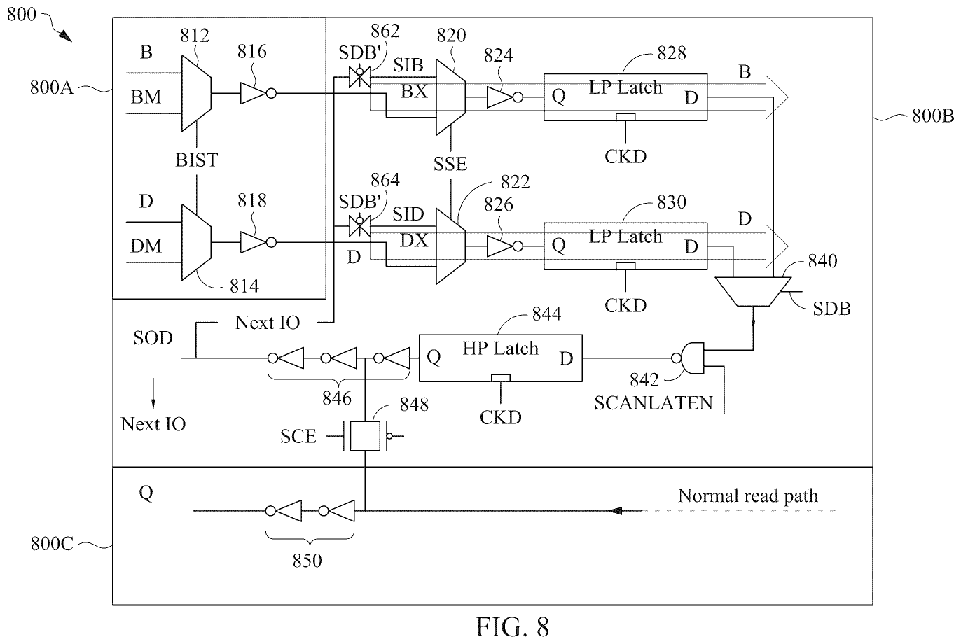

FIG. 8 illustrates an example circuit diagram of a portion of yet another I/O circuit 800, in accordance with various embodiments. It should be noted that the I/O circuit 800 has been simplified, with some components not expressively illustrated. For example, the I/O circuit 800 includes blocks 800A, 800B, and 800C. The blocks 800A and 800C may correspond to an input portion and an output portion of the I/O interface circuit 108 of the integrated circuit 100, respectively, and the block 800B may correspond to the I/O DFT circuit 106 of the integrated circuit 100. Accordingly, the blocks 800A, 800B, and 800C may sometimes be referred to as “input interface circuit 800A,” “DFT circuit 800B,” and “output interface circuit 800C,” respectively. Although not shown, it should be appreciated that the I/O circuit 800 also includes a corresponding I/O base circuit operatively coupled to the input interface circuit 800A, DFT circuit 800B, and output interface circuit 800C.

In some embodiments, the I/O circuit 800 is substantially similar to the I/O circuit 200 of FIG. 2, and thus, the following discussion will be focused on the difference between the I/O circuit 200 and the I/O circuit 800. The input interface circuit 800A and output interface circuit 800C are identical to the input interface circuit 200A and output interface circuit 200C, respectively. For example, the input interface circuit 800A also includes multiplexers 812 and 814 to receive input signal B/BM and input signal D/DM, respectively, and inverters (or otherwise buffers) 816 and 818; and the output interface circuit 800C also includes one or more inverters (or otherwise buffers) 850 to provide output signal Q. The DFT circuit 800B includes multiplexers 820 and 822, inverters (or otherwise buffers) 824 and 826, low-pass latches 828 and 830, a multiplexer 840, a NAND gate 842, a high-pass latch 844, one or more inverters (or otherwise buffers) 846, and a transmission gate 848. Each of the latches 828-730 and 844 may be implemented as a gated data latch, and the multiplexers 820-822 and 840 may be implemented as a SIMUX configured to shift input data into devices such as latches, in some embodiments. It should be understood that the low-pass latches 828-830 and high-pass latch 844 may be configured differently (e.g., other types of latches), while remaining within the scope of the present disclosure.

Different from the DFT circuit 200B, the DFT circuit 800B further includes transmission gates 862 and 864 coupled to the inputs of the multiplexers 820 and 822, respectively. Specifically, the transmission gate 862 is coupled between the output node of the DFT circuit 800B (that provides the signal SOD) and one of the inputs of the multiplexer 820, and the transmission gate 864 is coupled between the output node of the DFT circuit 800B (that provides the signal SOD) and one of the inputs of the multiplexer 822. Each of the transmission gates 862 and 864 is controlled by a different switching control signal SDB′ which is further processed based on (i) the switching control signal SDB that selects one of the B path or D path; and (ii) one of the input signal D or B. Further, the MUX compressor 840 may be controlled by such a processed control signal SDB′. In such a configuration, when a first one of the B path or D path is tested as having potential issues, a second one of the B path or D path can be tested again to assure whether the issues along the first tested path are confirmed. Further, when the DFT circuit 800B is coupled to multiple IO's, these IO's can be configured for testing any of their respective B paths or D paths.

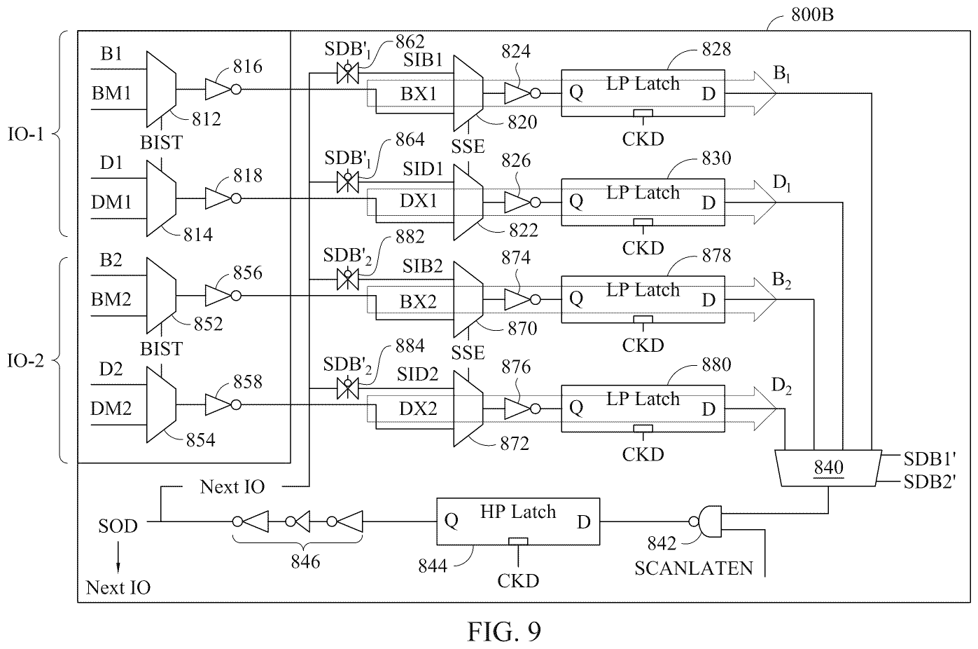

FIG. 9 illustrates an example where the DFT circuit 800B is coupled to a first IO (IO-1) and a second IO (IO-2). In addition to the components shown in FIG. 8 where the multiplexers 812 and 814 are configured to receive first input signal B₁/BM₁ and input signal D₁/DM₁, respectively, the DFT circuit 800B may include multiplexers 852 and 854 to receive second input signal B₂/BM₂ and input signal D₂/DM₂, respectively, and inverters (or otherwise buffers) 856 and 858, multiplexers 870 and 872, inverters (or otherwise buffers) 874 and 876, low-pass latches 878 and 880. The MUX compressor 840 can select one of the scan paths, B₁ path, D₁ path, B₂ path, or D₂ path based on control signals SDB₁′ and SDB₂′. The control signals SDB₁′ is generated by logically processing (i) a first switching control signal SDB₁ that selects one of the B₁ path or D₁ path; and (ii) one of the input signal D₁ or B₁; the control signals SDB₂′ is generated by logically processing (i) a second switching control signal SDB₂ that selects one of the B₂ path or D₂ path; and (ii) one of the input signal D₂ or B₂. In addition to the transmission gates 862 and 864, the DFT circuit 800B may further include transmission gates 882 and 884. The transmission gates 862-864 are controlled by the control signals SDB₁′, the transmission gates 882-884 are controlled by the control signals SDB₂′.

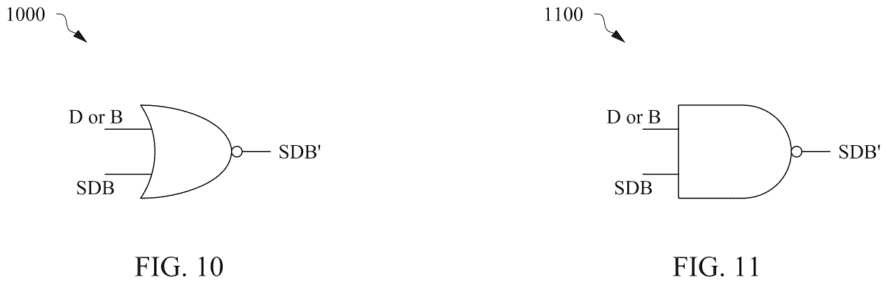

FIG. 10 and FIG. 11 respectively illustrate example logic gates 1000 and 1100 that can generate the above-discussed control signal SDB′, in accordance with various embodiments. In FIG. 10, the logic gate 1000 is a NOR gate that has two inputs, one of which is configured to receive the input signal B or D, and the other of which is configured to receive a corresponding switching control signal SDB, and one output that generates a control signal SDB′ that is a NOR'ed signal of the inputs. In FIG. 11, the logic gate 1100 is a NAND gate that has two inputs, one of which is configured to receive the input signal B or D, and the other of which is configured to receive a corresponding switching control signal SDB, and one output that generates a control signal SDB′ that is a NAND'ed signal of the inputs.

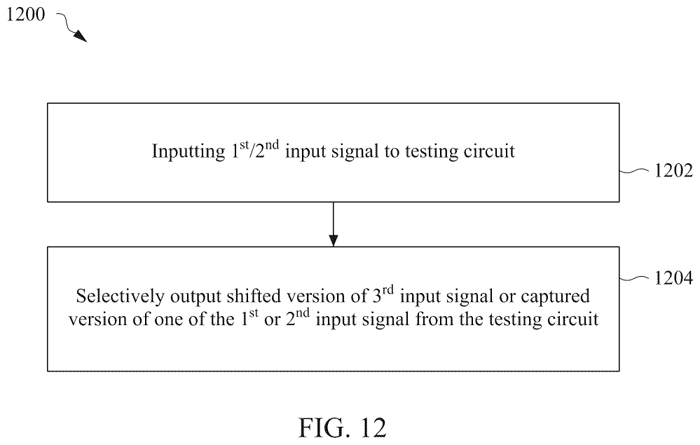

FIG. 12 illustrates a flow chart of an example method 1200 for testing at least a portion of an I/O circuit, in accordance with various embodiments. The method 1200 may be used to test an I/O circuit. For example, at least some of the operations described in the method 1200 can test any of the I/O circuit 200 (FIG. 2), 400 (FIG. 4), 500 (FIG. 5), 600 (FIG. 6), 700 (FIG. 7), or 800 (FIG. 8). It is noted that the method 1200 is merely an example and is not intended to limit the present disclosure. Accordingly, it is understood that additional operations may be provided before, during, and after the method 1200 of FIG. 12, and that some other operations may only be briefly described herein.

The method 1200 starts with operation 1202 in which a first input signal or a second input signal is input to a testing circuit. The testing circuit may include an I/O DFT circuit coupled to a functional circuit (e.g., one or more memory arrays and their operatively coupled I/O base circuit(s)), in various embodiments. Using the I/O circuit 200 (FIG. 2) as a representative example, the first input signal (e.g., input signal B/BM) or the second input signal (e.g., input signal D/DM) may be provided to the DFT circuit 200B through its input interface circuit 200A. In various embodiments, a logic state of one of the first or second input signal is independent of a logic state of the other of the first or second input signal.

The method 1200 continues to operation 1204 in which either a shifted version of a third input signal or a captured version of one of the first or second input signal is selectively output from the testing circuit. Continuing with the example of FIG. 2, the DFT circuit 200B can be operated under at least two modes to test the I/O circuit 200, a SHIFT mode and a CAPTURE mode. When configured in the SHIFT mode, the DFT circuit 200B may output a shifted version of the signal SID (the third input signal), which is a signal received from a previous scan chain (or previous I/O circuit); and when configured in the CAPTURE mode, the DFT circuit 200B may output a captured version of a selected one of the first or second input signal. In various embodiments, the MUX compressor 240 of the DFT circuit 200B can make the selection on the first or second input signal.

In one aspect of the present disclosure, a circuit is disclosed. The circuit includes an input/output (I/O) circuit operatively coupled to a functional circuit. The I/O circuit includes a testing circuit that includes: a plurality of first inputs corresponding to a first I/O of the I/O circuit and configured to receive at least a first input signal or a second input signal; a multiplexer compressor configured to select one of the first input signal or the second input signal for testing the I/O circuit; a first output configured to provide a first output signal based on a third input signal, when the testing circuit is configured in a first mode; and a second output configured to provide a second output signal based on the first or second input signal being selected by the multiplexer compressor, when the testing circuit is configured in a second mode. Regardless of the first input signal or the second input signal being selected, a logic state of the second input signal is independent of a logic state of the first input signal.

In another aspect of the present disclosure, a circuit is disclosed. The circuit includes a plurality of first inputs corresponding to a first I/O of an I/O circuit and configured to receive at least a first input signal or a second input signal. The circuit includes a multiplexer compressor coupled to the plurality of first inputs, and configured to alternately form a first testing path for the first input signal and a second testing path for the second input signal. The circuit includes a first output configured to provide a first output signal, through one of the first testing path or the second testing path, as a shifted version of a third input signal. The circuit includes a second output configured to provide a second output signal, through one of the first testing path or the second testing path, as a captured version of the first input signal or the second input signal.

In yet another aspect of the present disclosure, a method for testing an input/output (I/O) circuit is disclosed. The method includes inputting, to a testing circuit, a first input signal or a second input signal. A logic state of one of the first or second input signal is independent of a logic state of the other of the first or second input signal. The method includes selectively outputting, from the testing circuit, a shifted version of a third input signal that is received from a previous scan chain, or outputting a captured version of one of the first or second input signal.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit, comprising:
an input/output (I/O) circuit operatively coupled to a functional circuit, and comprising:
a testing circuit comprising:
a plurality of first inputs corresponding to the I/O circuit and configured to receive a plurality of first input signals;
a plurality of second inputs corresponding to the I/O circuit and configured to receive a plurality of second input signals;
a multiplexer compressor configured to output a signal generated based on one of the plurality of first input signals and one of the plurality of second input signals for testing according to a first control signal;
a first output configured to provide a first output signal based on a third input signal, when the testing circuit is configured in a first mode; and
a second output configured to provide a second output signal based on the signal outputted by the multiplexer compressor, when the testing circuit is configured in a second mode, wherein a second control signal or a third control signal causes the testing circuit to be configured in the first mode or the second mode, the second control signal and the third control signal being complementary to each other.

2. The circuit of claim 1, wherein the functional circuit includes one or more memory arrays, and wherein the first mode includes a shift mode, and the second mode includes a capture mode.

3. The circuit of claim 1, wherein a logic state of the one of the plurality of second input signals is independent of a logic state of the one of the plurality of first input signals.

4. The circuit of claim 1, wherein when the one of the plurality of first input signals has a first logic state, the one of the plurality of second input signals has a second logic state, wherein the first logic state is same as the second logic state.

5. The circuit of claim 1, wherein when the one of the plurality of first input signals has a first logic state, the one of the plurality of second input signals has a second logic state, wherein the first logic state is different than the second logic state.

6. The circuit of claim 1, wherein the I/O circuit comprises a first I/O that receives the one of the plurality of first input signals and the one of the plurality of second input signals.

7. The circuit of claim 1, wherein the I/O circuit comprises a plurality of I/Os, each of the plurality of I/Os configured to receive a first input signal and a second input signal.

8. The circuit of claim 1, wherein the testing circuit comprises a first multiplexer configured to receive the one of the plurality of first input signals and the one of the plurality of second input signals and output a first multiplexed signal.

9. The circuit of claim 8, wherein the testing circuit comprises a first inverter coupled to the first multiplexer configured to receive the first multiplexed signal and output an inverted signal.

10. The circuit of claim 9, wherein the testing circuit comprises a second multiplexer coupled to the first inverter and configured to receive the second control signal and the inverted signal and output a second multiplexed signal.

11. The circuit of claim 10, wherein the testing circuit comprises a second inverter and a lowpass latch, and wherein an input of the second inverter is coupled to an output of the second multiplexer, an output of the second inverter is coupled to an input of the lowpass latch, and an output of the lowpass latch is coupled to an input of the multiplexer compressor.

12. A circuit, comprising:
a plurality of first inputs configured to receive a plurality of first input signals;
a plurality of second inputs configured to receive a plurality of second input signals;
a multiplexer compressor configured to output a signal generated based on one of the plurality of first input signals and one of the plurality of second input signals for testing, wherein the one of the plurality of first input signals and the one of the plurality of second input signals are determined based on a first control signal;
a first output configured to provide a shifted version of a third input signal when the circuit is configured to operate in a shift mode; and
a second output configured to provide a captured version of the one of the plurality of first input signals or the one of the plurality of second input signals when the circuit is configured to operate in a capture mode.

13. The circuit of claim 12, wherein a second control signal or a third control signal causes the circuit to operate in the shift mode or the capture mode, the second control signal and the third control signal being complementary to each other.

14. The circuit of claim 12, wherein a logic state of the one of the plurality of second input signals and a logic state of the one of the plurality of first input signals are independent of each other.

15. The circuit of claim 13, wherein the circuit comprises a first multiplexer configured to receive the one of the plurality of first input signals and the one of the plurality of second input signals and output a first multiplexed signal.

16. The circuit of claim 15, wherein the circuit comprises a first inverter coupled to the first multiplexer and configured to receive the first multiplexed signal and output an inverted signal.

17. The circuit of claim 16, wherein the circuit comprises a second multiplexer coupled to the first inverter and configured to receive the second control signal and the inverted signal and output a second multiplexed signal.

18. The circuit of claim 17, wherein the circuit comprises a second inverter and a lowpass latch, and wherein an input of the second inverter is coupled to an output of the second multiplexer, an output of the second inverter is coupled to an input of the lowpass latch, and an output of the lowpass latch is coupled to an input of the multiplexer compressor.

19. A method for testing an input/output (I/O) circuit, comprising:
inputting, to a testing circuit, a first input signal or a second input signal, wherein a logic state of a first one of the first input signal and the second input signal is independent of a logic state of a second one of the first input signal and the second input signal; and
selectively outputting, according to a control signal by the testing circuit, a first output signal generated based on a previously received signal, or a second output signal based on the first input signal and the second input signal.

20. The method of claim 19, further comprising selecting, by a multiplexer of the testing circuit, the one of the first input signal or the second input signal.
